(19) United States
(12) Patent Application Publication
(10) Pub. No.: US 2012/0307452 A1
(43) Pub. Date: Dec. 6, 2012

(54) PORTABLE ELECTRONIC DEVICE WITH HEAT PIPE

(75) Inventors: QING-PING YAN, Shenzhen City (CN); DE-YU WANG, Shenzhen City (CN); JIANG-JUN HU, Shenzhen City (CN); CHUEN-SHU HOU, Tu-Cheng (TW)

(73) Assignees: FOXCONN TECHNOLOGY CO., LTD., Tu-Cheng (TW); FU ZHUN PRECISION INDUSTRY (SHEN ZHEN) CO., LTD., Shenzhen City (CN)

(21) Appl. No.: 13/236,660

(22) Filed: Sep. 20, 2011

(30) Foreign Application Priority Data
May 30, 2011 (CN) 201110142076.4

(51) Int. Cl. H05K 7/20; F28D 15/04

(52) U.S. Cl. 361/700; 165/104.26

(57) ABSTRACT

An exemplary portable electronic device includes a printed circuit board, a heat generating electronic component mounted on the printed circuit board, a shell housing the printed circuit board, the heat generating electronic component and a heat pipe therein. The heat pipe includes an evaporating side and a condensing side. The evaporating side thermally contacts the heat generating electronic component, and the condensing side thermally contacts the shell.

### BACKGROUND

1. Technical Field

The present disclosure relates to electronic devices, and particularly to a portable electronic device having a heat pipe.

2. Description of Related Art

The continuing and fast development of the electronic industry has resulted in a remarkable increase in the heat generated by electronic components. If this heat cannot be removed away in time from the electronic components, damage to the electronic components will be inevitable. On the other hand, the drive towards greater miniaturization is a prevalent tendency in the development of electronic equipment and this tendency further increases the difficulty of dissipating heat from electronic components.

What is needed, therefore, is a portable electronic device which can overcome the described limitations.

### BRIEF DESCRIPTION OF THE DRAWINGS

FIG. 1 is a partly cross sectional view of a portable electronic device according to a first embodiment of the present disclosure.

FIG. 2 is a partly cross sectional view of a portable electronic device according to a second embodiment of the present disclosure.

### DETAILED DESCRIPTION

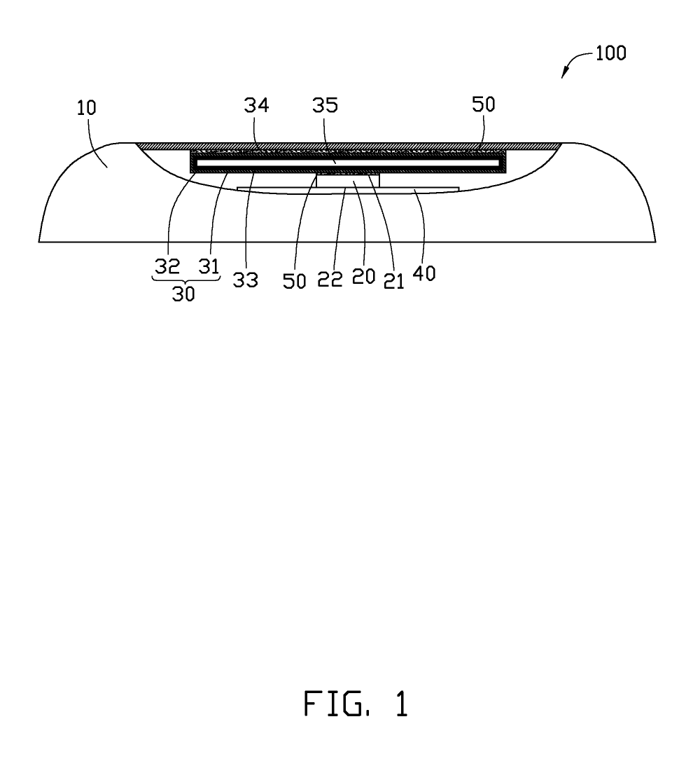

Referring to FIG. 1, a portable electronic device 100 is shown. The portable electronic device 100 includes a shell 10, a heat generating electronic component 20, a heat pipe 30, and a printed circuit board 40. The shell 10 houses the heat generating electronic component 20, the heat pipe 30, and the printed circuit board 40 therein to protect them. The heat generating electronic component 20 is mounted on the printed circuit board 40 and electrically connects the printed circuit board 40. The heat pipe 30 thermally contacts the heat generating electronic component 20 to absorb heat generated by the heat generating electronic component 20. The portable electronic device 100 may be an LCD, portable DVD player, tablet PC (personal computer), mobile phone etc. In this embodiment, the portable electronic device 100 is a tablet PC. The heat pipe 30 is a flattened heat pipe.

The heat generating electronic component 20 is planar and includes a planar first surface 21 and a planar second surface 22 opposite to the first surface 21. A size of the heat pipe 30 is not less than that of the heat generating electronic component 20. In this embodiment, the size of the heat pipe 30 is larger than that of the heat generating electronic component 20. The first surface 21 is adhered to a central portion of a bottom side of the heat pipe 30 by thermal grease 50 laid therebetween. The second surface 22 is adhered on the printed circuit board 40 to fix the heat generating electronic component 20 on the printed circuit board 40.

The heat pipe 30 includes a casing 31, a wick structure 32 arranged on an inner surface of the casing 31, and working fluid (not shown) contained in the casing 31.

The casing 31 is rectangular and sealed, and includes an evaporating side 33 and a condensing side 34 located at opposite sides thereof. A central portion of the evaporating side 33 thermally contacts the first surface 21 of the heat generating electronic component 20 to absorb heat generated from the heat generating electronic component 20. The first surface 21 of the heat generating electronic component 20 is adhered to the central portion of the evaporating side 33 by the thermal grease 50 laid therebetween. The condensing side 34 is assembled to an inner surface of the shell 10 by the thermal grease 50 laid therebetween to transfer heat absorbed from the heat generating electronic component 20 to the shell 10.

The wick structure 32 is continuous and arranged on the inner surface of the casing 31. A channel 35 is defined in the casing 31 and enclosed by the wick structure 32 to allow vaporized working fluid circulating therein. The wick structure 32 is made of sintered metallic powder and includes a plurality of pores (not shown) therein. In the other embodiment, the wick structure 32 is formed by weaving a plurality of wires etc.

The heat pipe 30 is thin to suitable for the portable electronic device 100. In this embodiment, a thickness of the heat pipe 30 is varied between 1 millimeter and 3 millimeter. Thus, the heat pipe 30 can intimately contacts the heat generating electronic component 20 and the shell 10.

When the portable electronic device 100 is operated, the evaporating side 33 of the heat pipe 30 thermal contacts the heat generating electronic component 20. The working fluid at the evaporating side 33 absorbs heat generated by the heat generating electronic component 20, and thereby turns to vapor. Due to the difference in vapor pressure between the evaporating side 33 and the condensing side 34 of the heat pipe 30, the generated vapor moves in the channel 35, carrying the heat with it, toward the condensing side 34. At the condensing side 34, the vapor condenses after transferring the heat to the shell 10. The shell 10 then releases the heat into the ambient environment. The condensed working fluid is drawn back by the wick structure 32 to the evaporating side 33 where it is again available for evaporation.

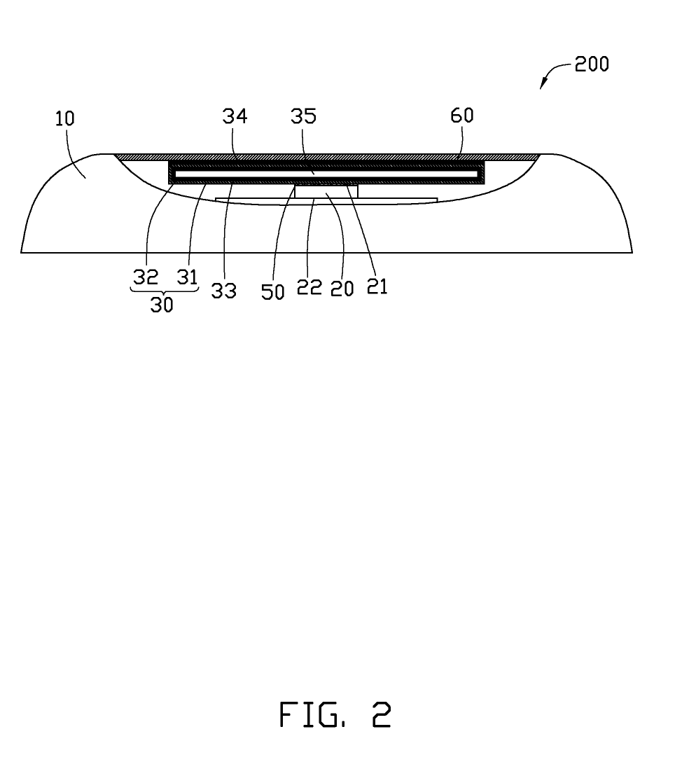

Referring to FIG. 2, a portable electronic device 200 is shown. The portable electronic device 200 is similar to the portable electronic device 100, except that the heat pipe 30 is sintered to the inner surface of the shell 10 by solder 60 laid between the heat pipe 30 and the inner surface of the shell 10.

It is to be understood, however, that even though numerous characteristics and advantages of the embodiment(s) have been set forth in the foregoing description, together with details of the structures and functions of the embodiment(s), the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A portable electronic device comprising:
a printed circuit board;
a heat generating electronic component mounted on the printed circuit board;
a heat pipe, the heat pipe comprising an evaporating side and a condensing side; and
a shell housing the printed circuit board, the heat generating electronic component therein and heat pipe therein;
wherein the evaporating side thermally contacts the heat generating electronic component, and the condensing side thermally contacts the shell.

2. The portable electronic device of claim 1, wherein the heat pipe is flattened and the evaporating side and the condensing side are located at opposite sides thereof.

3. The portable electronic device of claim 2, wherein the heat pipe comprises a casing, a wick structure arranged on an inner surface of the casing and working fluid contained in the casing.

4. The portable electronic device of claim 3, wherein a channel is defined in the casing and enclosed by the wick structure to allow vaporized working fluid circulating therein.

5. The portable electronic device of claim 1, wherein the condensing side of the heat pipe is adhered to the inner surface of the shell by glue laid therebetween.

6. The portable electronic device of claim 1, wherein the condensing side of the heat pipe is sintered to the inner surface of the shell by solder laid therebetween.

7. The portable electronic device of claim 1, wherein the heat generating electronic component is adhered to the evaporating side by glue laid therebetween.

8. The portable electronic device of claim 1, wherein a thickness of the heat pipe is varied between 1 millimeter and 3 millimeter.

9. A portable electronic device comprising:
a shell defining a space therein;
a heat generating electronic component received in the space of the shell; and
a heat pipe received in the shell, the heat pipe comprising an evaporating side and a condensing side, the evaporating side attaching to the heat generating electronic component, the condensing side attaching to the shell, thereby transferring heat of the heat generating component to the shell for dissipation.
